(19) United States
(12) Patent Application Publication
(10) Pub. No.: US 2009/0302376 A1
(43) Pub. Date: Dec. 10, 2009

(54) SEMICONDUCTOR DEVICE

(75) Inventors: Naoyuki INOUE, Hyogo-Ken (JP); Wataru SAITO, Kawasaki-Shi (JP); Satoshi AIDA, Himeji-Shi (JP); Masakatsu TAKASHITA, Kawasaki-Shi (JP); Koichi ARATANI, Hakusan-Shi (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/474,073

(22) Filed: May 28, 2009

(30) Foreign Application Priority Data
May 28, 2008 (JP) 2008-139603

(51) Int. Cl. H01L 29/78

(52) U.S. Cl. 257/329; 257/409; 257/E29.257

(57) ABSTRACT

A semiconductor device includes: a first semiconductor layer of a first conductivity type having a first surface and a second surface opposite to the first surface, a cell region, and a terminal region surrounding the cell region, the cell region being configured to allow a current to flow between the first surface and the second surface; a first guard ring layer of a second conductivity type selectively formed in a surface portion of the first semiconductor layer in the terminal region, the first guard ring layer having a bottom surface thereof and internal and external side surfaces thereof; and a second guard ring layer of the second conductivity type selectively formed in the surface portion of the first semiconductor layer in the terminal region so as to cover a portion of the first guard ring layer at which the bottom surface and the external side surface intersect.

### CROSS REFERENCE TO RELATED APPLICATION

This application claims benefit of priority under 35 USC §119 to Japanese Patent Application No. 2008-139603, filed on May 28, 2008, the contents of which are incorporate by reference herein.

### BACKGROUND OF THE INVENTION

1. Field of the Invention

The present invention relates to a semiconductor device.

2. Related Background Art

On-resistance in a vertical semiconductor power device is determined by electric resistance in a path through which electrons flow. Taking a vertical power MISFET (Metal Insulator Semiconductor Field Effect Transistor) for example, in an on-state, electrons flow in JFET regions sandwiched by P-base layers via a MOS channel from a source electrode, flow into a drift layer, and reach a drain electrode. There are three dominant elements of the on-resistance, which are resistance in the JFET regions, resistance against electrons spreading from the JFET regions to the entire drift layer, and resistance in the drift layer.

To decrease the drift resistance, it is effective to decrease the thickness of the drift layer and increase its impurity concentration. However, this interrupts expansion of a depletion layer and decreases a breakdown voltage. Therefore, the drift resistance cannot be decreased to a level equal to or under a predetermined limit.

Consequently, by decreasing the JFET resistance and spreading resistance that do not easily affect the breakdown voltage, the on-resistance can be decreased while maintaining a high breakdown voltage.

To decrease the JFET resistance, it suffices that impurity concentration of the JFET regions is increased. Usually, this impurity concentration is increased higher than that of the drift layer (for example, Japanese Patent Application Laid-open No. 2002-246595). By deeply diffusing a high impurity concentration N layer in the JFET regions (JFET-N layers), the spreading resistance can be decreased.

However, when the impurity concentration is increased, the depletion layer does not easily expand, and avalanche breakdown occurs in the JFET layers, not in the drift layer, and this results in decreasing the breakdown voltage. When the JFET-N layers are diffused deeper than the P-base layers, impurity concentration at P-base layer bottoms becomes high, and the breakdown voltage decreases in a similar manner to that when the impurity concentration of the drift layer is increased. Therefore, there is also a limit to decreasing the JFET resistance and the spreading resistance.

### SUMMARY OF THE INVENTION

According to a first aspect of the present invention, there is provided a semiconductor device comprising:

a first semiconductor layer of a first conductivity type comprising a first surface and a second surface opposite to the first surface, a cell region, and a terminal region surrounding the cell region, the cell region being configured to allow a current to flow between the first surface and the second surface;

a first guard ring layer of a second conductivity type selectively formed in a surface portion of the first semiconductor layer in the terminal region, the first guard ring layer comprising a bottom surface thereof and internal and external side surfaces thereof; and

a second guard ring layer of the second conductivity type selectively formed in the surface portion of the first semiconductor layer in the terminal region so as to cover a portion of the first guard ring layer at which the bottom surface and the external side surface intersect, the impurity concentration of the second guard ring being a level at which the second guard ring layer is completely depleted by application of a high voltage.

### BRIEF DESCRIPTION OF THE DRAWINGS

In the drawings:

FIG. 1 is a cross-sectional view schematically showing a configuration of a semiconductor device according to a first embodiment of the present invention;

FIG. 2 is a cross-sectional view showing a modification of the semiconductor device shown in FIG. 1;

FIG. 3 is a cross-sectional view schematically showing a configuration of a semiconductor device according to a second embodiment of the present invention;

FIG. 4 is a cross-sectional view schematically showing a configuration of a semiconductor device according to a third embodiment of the present invention;

FIG. 5 is a cross-sectional view showing a modification of the semiconductor device shown in FIG. 4;

FIG. 6 is a cross-sectional view schematically showing a configuration of a semiconductor device according to a fourth embodiment of the present invention;

FIG. 7 is a cross-sectional view showing a first modification of the semiconductor device shown in FIG. 6;

FIG. 8 is a cross-sectional view showing a second modification of the semiconductor device shown in FIG. 6;

FIG. 9 is a cross-sectional view schematically showing a configuration of a cell region of a semiconductor device according to a fifth embodiment of the present invention and an electric field distribution thereof;

FIG. 10 is a graph showing optimum NpWp of P⁻ layers as a ratio with respect to NnWn of JFET-N layers in the semiconductor device shown in FIG. 9;

FIG. 11 is a cross-sectional view showing a first modification of the semiconductor device shown in FIG. 9;

FIG. 12 is a cross-sectional view showing a second modification of the semiconductor device shown in FIG. 9;

FIG. 13 is a cross-sectional view schematically showing a configuration of a semiconductor device according to a sixth embodiment of the present invention;

FIG. 14 is a cross-sectional view showing a modification of the semiconductor device shown in FIG. 13;

FIG. 15 is a cross-sectional view schematically showing a configuration of a semiconductor device according to a seventh embodiment of the present invention;

FIG. 16 is a cross-sectional view showing a first modification of the semiconductor device shown in FIG. 15;

FIG. 17 is a cross-sectional view showing a second modification of the semiconductor device shown in FIG. 15;

FIG. 18 is a cross-sectional view schematically showing a configuration of a semiconductor device according to an eighth embodiment of the present invention;

FIG. 19 is a cross-sectional view showing a first modification of the semiconductor device shown in FIG. 18;

FIG. 20 is a cross-sectional view showing a second modification of the semiconductor device shown in FIG. 18;

FIG. 21 is a cross-sectional view showing a third modification of the semiconductor device shown in FIG. 18; and

FIG. 22 is a cross-sectional view showing a fourth modification of the semiconductor device shown in FIG. 18.

### DETAILED DESCRIPTION OF THE INVENTION

Embodiments of the present invention will be explained below with reference to the accompanying drawings. In the following embodiments, a first conductive type is expressed as N-type, and a second conductive type is expressed as P-type. In addition, like parts in the drawings are denoted by like reference numerals and redundant explanations thereof will be properly omitted.

### (1) First Embodiment

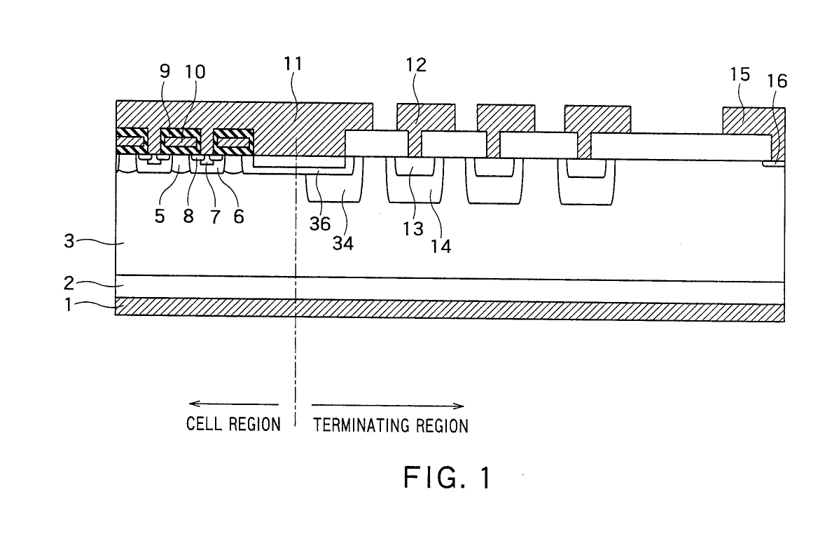

FIG. 1 is a cross-sectional view schematically showing a configuration of a semiconductor device according to a first embodiment of the present invention. The present embodiment has a characteristic in that two-stage guard ring layers having impurity concentrations different to each other are provided in a terminating region, as described later.

The semiconductor device shown in FIG. 1 is a vertical power MOSFET, and has a cell region in which a MOSFET is formed and a terminating region positioned at the outside of the cell region when viewed from the cell region to surround the cell region.

In the cell region, P-base layers 6 are selectively formed in a surface layer of an N⁻ drift layer 3, and JFET-N layers 5 are selectively formed so as to be sandwiched by the P-base layers 6. The JFET-N layers 5 are formed so as to have impurity concentration higher than that of the N⁻ drift layer 3. Therefore, resistance of JFET regions sandwiched by the P-base layers 6 can be decreased. N⁺ source layers 8 are selectively formed in the surface layer of the P-base layers 6, and P⁺ contact layers 7 are formed so as to be sandwiched by the N⁺ source layers 8.

Gate electrodes 10 are formed via gate dielectric films 9 having a film thickness about 0.1 μm, for example, a silicon oxide films. Each of the silicon oxide films is formed in a region on the N⁻ drift layer 3 extending from a N⁺ source layer 8 at a first end of one P-base layer 6 to a neighboring N⁺ source layer 8 at a second end of a neighboring P-base layer 6 facing the first end via a JFET-N layer 5. A source electrode 11 is formed so as to contact the P-base layers 6 and the N⁺ source layers 8 within the regions sandwiched by the neighboring gate dielectric films 9.

An N⁺ drain layer 2 is formed as a high-impurity concentration semiconductor layer on a surface of the N⁺ drain layer 2 opposite to a surface of the N⁺ drain layer 2 where the P-base layers 6 are formed. A drain electrode 1 is formed on a surface of the N⁺ drain layer 2 so as to be in contact with a surface of the N⁺ drain layer 2 opposite to a surface of the N⁺ drain layer 2 in contact with the N⁻ drift layer 3. The N⁻ drift layer 3 and the N⁺ drain layer 2 can be formed, by impurity diffusion from one surface of the N⁻ drift layer 3, or by crystal growth of the N⁻ drift layer 3 with the use of the N⁺ drain layer 2 as a substrate. In the present embodiment, the N⁻ drift layer 3 corresponds to a first semiconductor layer, for example.

In this embodiment, the P-base layer 6 corresponds to, e.g. a second semiconductor layer, and the JFET-N layer 5 corresponds to, e.g. a third semiconductor layer. In addition, in this embodiment, the N⁺ source layers 8 corresponds to, e.g. a fourth semiconductor layer, the gate electrode 10 corresponds to, e.g. a control electrode, and drain electrode 1 and source electrode 11 correspond to, e.g. first and second main electrodes, respectively.

In the terminating region, guard ring layers 13 having first impurity concentration are formed in the surface layer of the N⁻ drift layer 3. Further, guard ring layers 14 having second impurity concentration lower than the first impurity concentration are formed so as to cover the guard ring layers 13 from a bottom surface thereof. Field plate electrodes 12 are formed on the guard ring layers 13. A field stop electrode 15 and a field stop layer 16 are formed at a peripheral edge so that a depletion layer extended in the lateral direction of the terminating region does not reach a side wall of a chip when a high-voltage is applied. In the present embodiment, the guard ring layers 13 and 14 correspond to, for example, first and second guard ring layers, respectively.

Near the boundary between the cell region and the terminating region, the depletion layer is extended toward a peripheral edge of the device from an end of the P-base layers 6 connected to the source electrode 11 on a boundary side. Therefore, electric fields tend to be concentrated at the end portion of the P-base layers 6 on the boundary side. When the P-base layers 6 become shallow, a curvature radius of the end of the P-base layers 6 in a cross-sectional direction becomes small, and electric field concentration becomes conspicuous, resulting in decreasing of the breakdown voltage.

The guard ring layers 13 are formed to relax the electric field concentration at the end of the boundary side of the P-base layers 6. The guard ring layers 13 can be formed simultaneously with the P-base layers 6. However, when the guard ring layers 13 as well as the P-base layers 6 are formed shallowly, for example, electric field concentration becomes conspicuous in a portion of the guard ring layers 13 (hereinafter, “external end portion”) in a region where an external side surface intersects with a bottom surface of the guard ring layers 13 out of both side surfaces of the guard ring layers 13 as viewed from the cell region. Consequently, avalanche breakdown occurs in the external end portion of the guard ring layers 13, and the breakdown voltage decreases. Thus, the guard ring layers 14 are formed as P⁻ guard ring layers to cover the guard ring layers 13 from the bottom surface thereof, thereby securely suppressing decrease of the breakdown voltage. In a region close to the cell region out of the terminating region, a shallow P layer 36 is uniformly formed in the surface layer of the N⁻ drift layer. A P⁻ layer 34 is formed to cover an external end portion of the P layer 36 from below. Also with this arrangement, electric field concentration is relaxed and decrease of the breakdown voltage is suppressed.

Because the field plate electrodes 12 are provided, there is an advantage that a charge on the chip surface does not easily affect breakdown voltage and reliability of the device. Even when impurity concentration of the P⁻ guard ring layers 14 has a variation, there is an advantage that a stable termination breakdown voltage can be achieved.

While FIG. 1 shows a configuration including three of the guard ring layers 13 and three of the guard ring layers 14, the number of the guard ring layers is not limited to three, and can be one or two, or four or more.

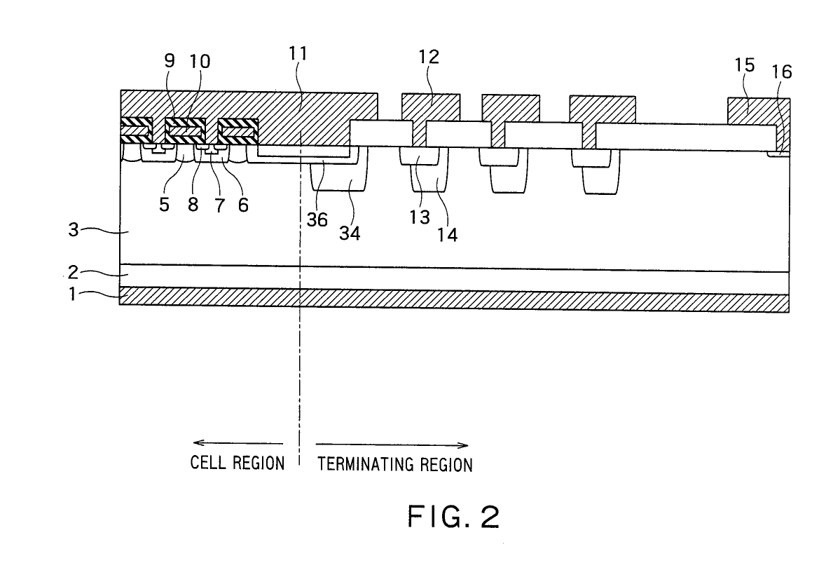

FIG. 2 shows a modification of the present embodiment. In the example shown in FIG. 2, the guard ring layers 14 are formed to cover only the external end portion of the guard ring layers 13. A stable termination breakdown voltage can be also obtained even in this configuration.

As explained above, high reliability is achieved by forming the guard ring layers 14 to cover the guard ring layers 13 from the bottom surface thereof to reach the surface of the N⁻ drift layer 3 becoming an interface with the oxide film. By forming the guard ring layers 14 so as to reach the surface of the N⁻ drift layer 3, an electric field in a region near a region where the guard ring layers 13 and the guard ring layers 14 are in contact with the oxide film decreases. Consequently, impact ionization does not easily occur when a high-voltage is applied, and high reliability is achieved.

To achieve the reliability, the guard ring layers 14 have impurity concentration at a level at which the guard ring layers 14 are completely depleted when a high voltage is applied to the guard ring layers 14.

Further, a shape of the guard ring layers 14 covering the guard ring layers 13 from their bottom surface to reach the surface of the N⁻ drift layer 3 can be formed by a self-alignment process. Therefore, there is no matching deviation and consequently an end length of the device can be shortened.

### (2) Second Embodiment

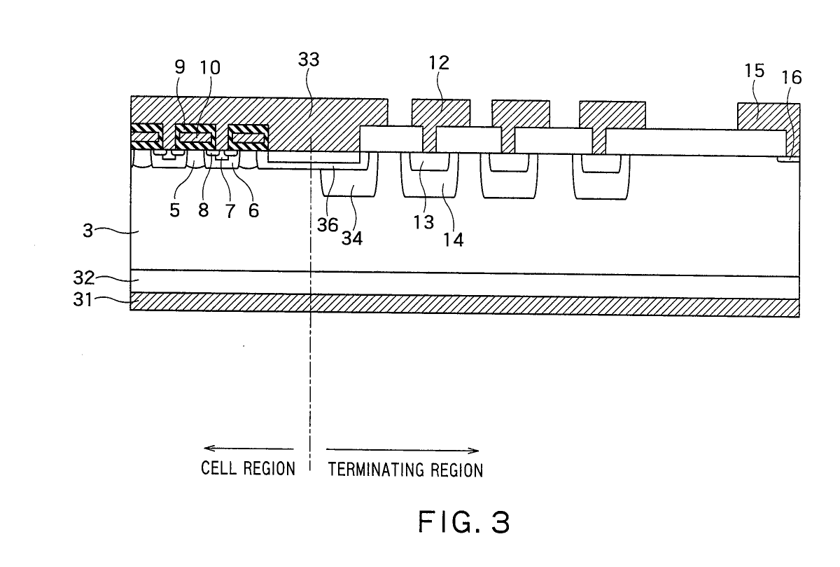

FIG. 3 is a cross-sectional view schematically showing a configuration of a semiconductor device according to a second embodiment of the present invention.

The semiconductor device shown in FIG. 3 is an embodiment in which the present invention is applied to an IGBT (Insulated Gate Bipolar Transistor). This semiconductor device includes a P⁺ layer 32, a collector electrode 31, and an emitter electrode 33, in place of the N⁺ drain layer, the drain electrode 1, and the source electrode 11 in the configuration shown in FIG. 1. In this embodiment, the P-base layer 6 corresponds to, e.g. a second semiconductor layer, and the JFET-N layer 5 corresponds to, e.g. a third semiconductor layer, the N⁺ source layers 8 corresponds to, e.g. a fourth semiconductor layer and the P⁺ layer 32 corresponds to, e.g. a sixth semiconductor layer. In addition, in this embodiment, the gate electrode 10 corresponds to, e.g. a control electrode, and the collector electrode 31 and emitter electrode 33 correspond to, e.g. first and second main electrodes, respectively.

As explained above, even when the present invention is applied to an IGBT, the guard ring layers 13 and 14 at two stages of high and low are formed in the terminating region. Therefore, a stable termination breakdown voltage can be obtained.

### (3) Third Embodiment

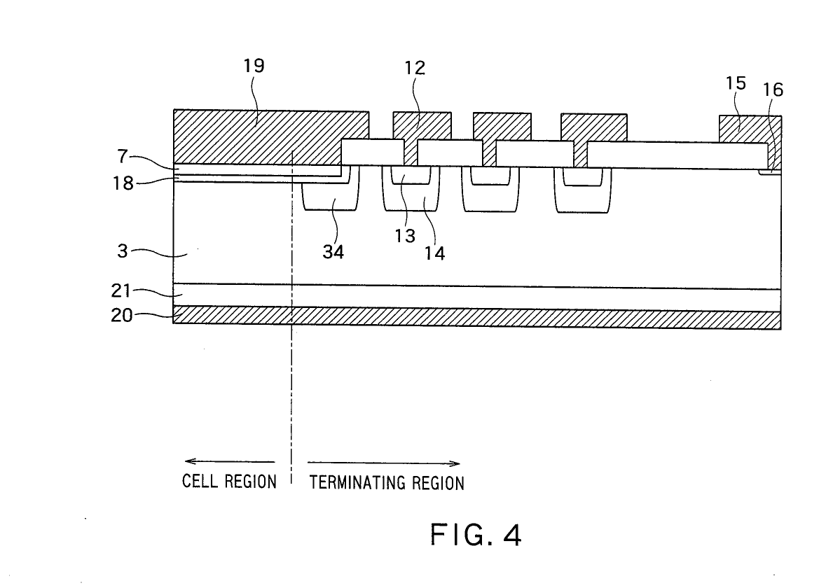

FIG. 4 is a cross-sectional view schematically showing a configuration of a semiconductor device according to a third embodiment of the present invention. The semiconductor device shown in FIG. 4 is an embodiment in which the present invention is applied to a PN-junction diode.

Specifically, in the cell region, in place of the MOSFET shown in FIG. 1, a P anode layer 18 is formed in the surface layer of the N⁻ drift layer 3, and P⁺ contact layers 7 are formed in a surface layer of the P anode layer 18. An anode electrode 19 is formed on one surface of the N⁻ drift layer 3 so as to be in contact with the P⁺ contact layers 7. An N⁺ cathode layer 21 is formed on a cathode side opposite to an anode side so as to be in contact with the N⁻ drift layer 3. Furthermore, a cathode electrode 20 is formed to be in contact with the N⁺ cathode layer 21. A configuration of the terminating region in the present embodiment is substantially the same as the configuration shown in FIG. 1.

In this embodiment, the P anode layer 18 corresponds to, e.g. a second semiconductor layer, the anode electrode 19 corresponds to, e.g. a first main electrode and the cathode electrode 20 corresponds to, e.g. a second main electrode.

As explained above, even when the present invention is applied to a configuration of a diode, a stable termination breakdown voltage can be obtained.

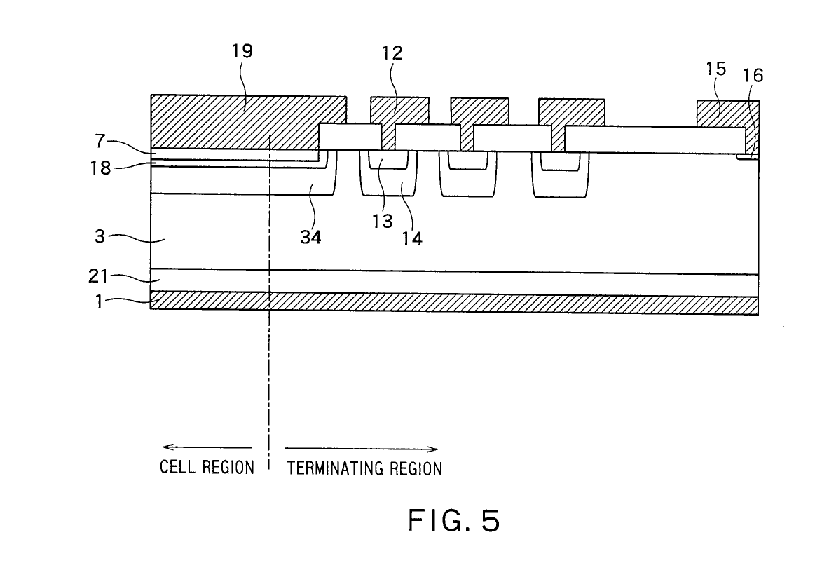

FIG. 5 shows a modification of the present embodiment. In the example shown in FIG. 5, a diode configuration having the P⁻ layer 34 also formed on the whole surface of the cell region is formed. Based on this configuration, decrease of a breakdown voltage in an external end portion of the P⁻ layer 34 can be suppressed.

### (4) Fourth Embodiment

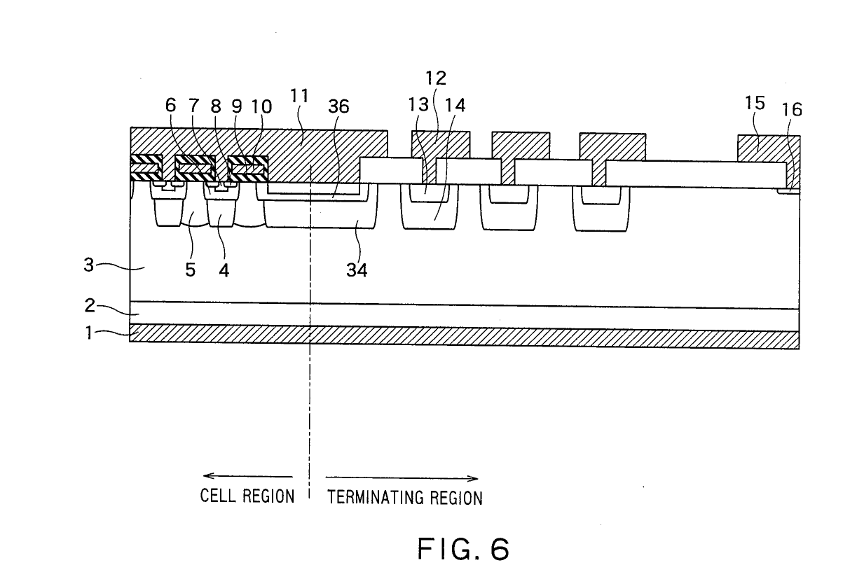

FIG. 6 is a cross-sectional view schematically showing a configuration of a semiconductor device according to a fourth embodiment of the present invention.

As is clear from a comparison between FIG. 1 and FIG. 6, the present embodiment has a characteristic in that P⁻ layers 4 are formed in the surface layer of the N⁻ drift layer 3 so as to be in contact with a bottom surface of the P-base layers 6 in the cell region, and that the JFET-N layers 5 are formed deeper than the P-base layers 6. In the present embodiment, the P⁻ layers 4 correspond to, for example, a fifth semiconductor layer.

As explained above, according to a power MOSFET of the present embodiment, the P⁻ layers 4 are provided beneath the P-base layers 6. Therefore, a breakdown voltage does not decrease even when the JFET-N layers 5 are formed deeper than the P-base layers 6. Consequently, lowering of on-resistance can be achieved while maintaining a high breakdown voltage.

The JFET-N layers 5 and the P⁻ layers 4 can be formed by implanting impurity ion from the surface of the N⁻ drift layer 3, and by performing a thermal diffusion process. When the P⁻ layers 4 are diffused deeply, the JFET-N layers can be also diffused deeply. An effective depth of the P⁻ layers 4 corresponds to a difference obtained by subtracting a depth of the P-base layers 6 from a depth of the bottom of the P⁻ layers 4. Therefore, when the P-base layers 6 are formed shallowly, the effective depth of the P⁻ layers 4 increases, and the effect of lowering of on-resistance improves.

However, when the P-base layers 6 are formed shallowly, a breakdown voltage in the terminating region decreases. In the terminating region, a depletion layer is extended toward the outside from an end portion of the P-base layers 6 connected to the source electrode on a boundary side. Therefore, electric fields tend to be concentrated in the end portion of the P-base layers 6 on the boundary side. When the P-base layers 6 become shallow, a curvature radius of the end portion on the external side in a cross-sectional direction becomes small, and electric field concentration becomes conspicuous, resulting in decrease of the breakdown voltage.

To prevent decrease of such a breakdown voltage, the P⁻ layers 4 are formed to cover the bottom surface of the P-base layers 6. As a result, decrease of the breakdown voltage can be suppressed. Further, when the P⁻ layers 4 are formed deeply, a curvature radius of the end portion of the P-base layers 6 on the external side in a cross-sectional direction can be increased. Consequently, a high breakdown voltage can be achieved.

The guard ring layers 13 are formed to further relax electric field concentration of the end portion of the P-base layers 6 on the boundary side, and the P⁻ guard ring layers 14 are formed to cover at least the external end portion of the guard ring layers 13. With this arrangement, decrease of the breakdown voltage can be suppressed.

The P⁻ guard ring layers 14 can be formed simultaneously with the P⁻ layers 4. When these layers are formed simultaneously, a depth of the P⁻ guard ring layers 14 is equal to a depth of the P⁻ layers 4. When the P-base layers 6 and the guard ring layers 13 are also formed simultaneously, depths of these layers become equal.

In the example shown in FIG. 6, the terminating region has three guard ring layers 13. Because the P⁻ layers 4 are formed, decrease of the breakdown voltage can be suppressed even when there is no guard ring layer. The number of the guard ring layers 13 provided in the terminating region is not limited to three, and of course can be one or two, or four or more.

The present embodiment has an advantage that by providing the field plate electrodes 12, a charge on the chip surface does not easily affect breakdown voltage and reliability of the device. In addition, the present embodiment has another advantage in that a stable termination breakdown voltage can be obtained even when impurity concentration of the P⁻ guard ring layers 14 varies.

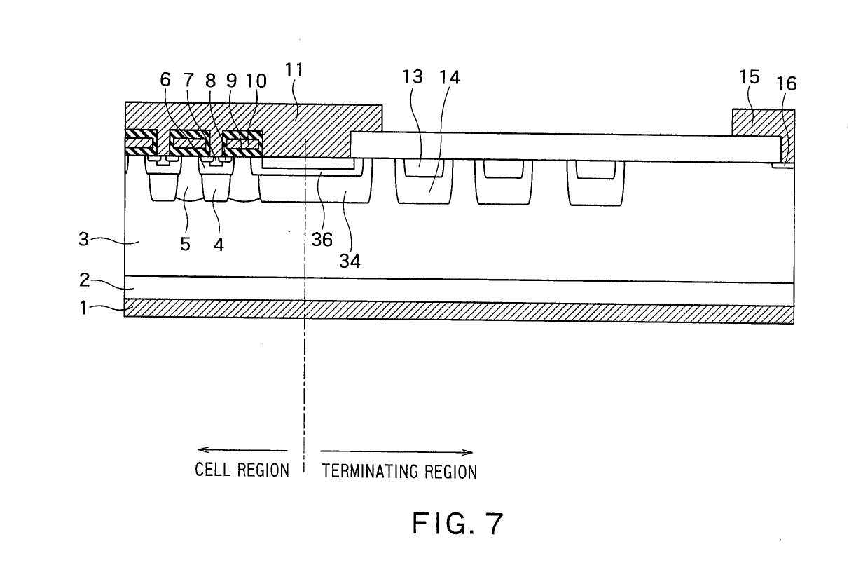

On the other hand, as shown in a first modification in FIG. 7, the invention can be implemented without the field plate electrode 12. By forming no field plate electrodes 12, there is an advantage that the width of the guard ring layers 13 and the width of the P⁻ guard ring layers 14 can be made small, thereby shortening an end length.

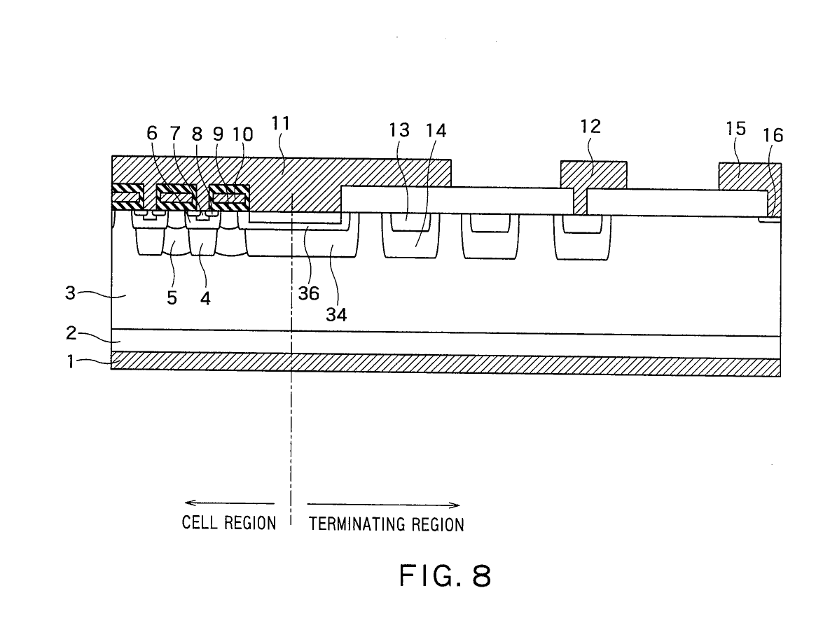

Further, as shown in a second modification in FIG. 8, a stable breakdown voltage and high reliability can be achieved and an end length can be shortened, by forming the field plate electrodes 12 to be connected to only a part of the guard ring layers.

### (5) Fifth Embodiment

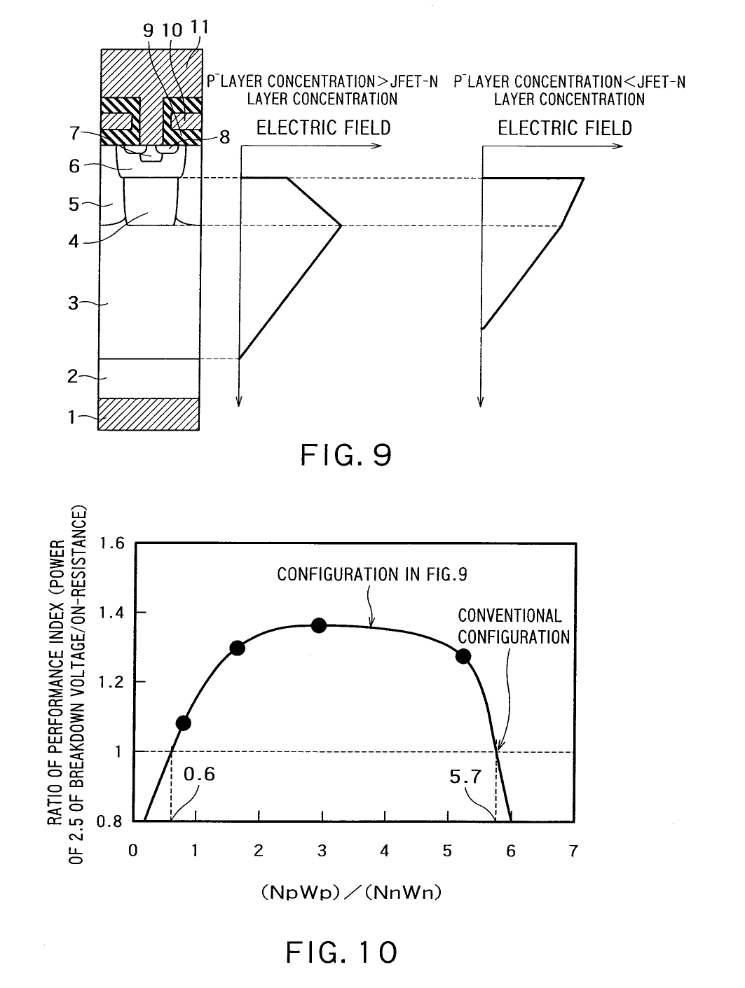

FIG. 9 is a cross-sectional view schematically showing a configuration of a cell region of a semiconductor device and an electric field distribution according to a fifth embodiment of the present invention. Detailed explanations of the same parts as those in FIG. 6 are omitted, and only different parts are explained here.

As shown in FIG. 9, lowering of on-resistance can be achieved by forming the P⁻ layers 4 and the JFET-N layers 5 deeper than the bottom surface of the P-base layer 6. However, when the P⁻ layers 4 are not completely depleted, there is a similar effect to that the drift layer 3 holding a voltage becomes thinner when the P⁻ layers 4 become deeper. Consequently, a breakdown voltage decreases. Therefore, the P⁻ layers 4 need to be completely depleted by applying a high voltage to the P⁻ layers 4.

By completely depleting the P⁻ layers 4, even the P⁻ layers 4 can hold a voltage. By optimizing impurity concentration of the P⁻ layers 4, a high breakdown voltage can be achieved. As shown in an electric-field distribution diagram in the upper left portion of the sheet of FIG. 9, when impurity concentration of the P⁻ layers 4 is set higher than that in the JFET-N layers 5, there is an effect similar to that when the entirety of the P⁻ layers 4 and the JFET-N layers 5 is doped in the P-type. Therefore, the electric field distribution becomes such that an electric field peak is at a bottom of the P⁻ layers 4. Accordingly, an electric field within the N⁻ drift layer 3 becomes large, and an inclination of the electric field within the N⁻ drift layer 3 can be increased. Because the inclination of the electric field is proportional to impurity concentration, impurity concentration of the N⁻ drift layer 3 can be increased, and drift resistance can be decreased.

On the other hand, as shown in the electric-field distribution diagram in the upper right portion of the sheet of FIG. 9, when impurity concentration of the P⁻ layers 4 is set lower than impurity concentration of the JFET-N layers 5 and to a level lower than predetermined impurity concentration, there is an effect similar to that when the entirety of the P⁻ layers 4 and the JFET-N layers 5 is doped in the N-type. Therefore, the electric field peak shifts to a bottom of the P-base layers 6. Accordingly, an electric field in the N⁻ drift layer 3 becomes small, and a high breakdown voltage cannot be obtained.

When a high voltage is applied, a depletion layer is extended in a lateral direction from a PN junction of the P⁻ layers 4 and the JFET-N layers 5 each of which is vertically formed, resulting in complete depletion. Therefore, strictly speaking about impurity concentration, a product of impurity concentration (cm⁻³) and a width in a direction in which a MOS transistor is cyclically and repetitively formed is important. In general, it is preferable that a relationship of NpWp>NnWn is realized. In NpWp>NnWn, Np represents impurity concentration of the P⁻ layers 4, Wp represents a width of the P⁻ layers 4 in the horizontal direction in the sheet of FIG. 9, Nn represents impurity concentration of the JFET-N layers 5, and Wn represents a width of the JFET-N layers 5 in the horizontal direction in the sheet of FIG. 9. In the present embodiment, the horizontal direction in the sheet of FIG. 9 corresponds to a first direction, for example.

On the other hand, when the impurity concentration Np of the P⁻ layers 4 is excessively increased relatively to the impurity concentration Nn of the JFET-N layers 5, the JFET-N layers 5 become easily depleted. Thus, on-resistance increases rapidly when a drain current flows. Therefore, as a method of controlling an electric-field peak position, it is preferable to set NpWp to a value within the range from 0.6 times NnWn to 5.7 times NnWn.

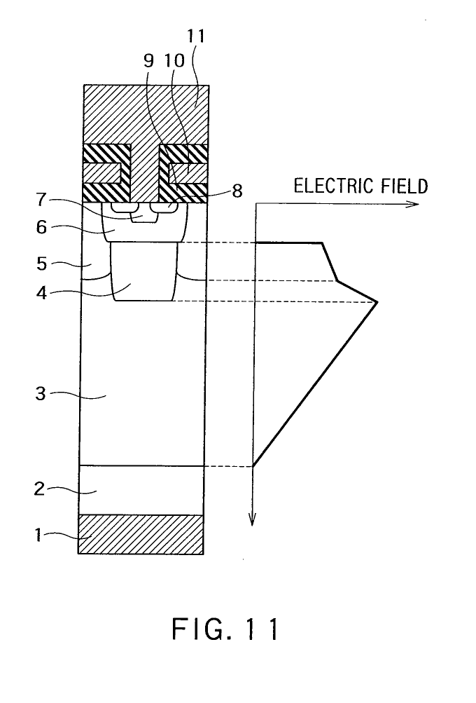

FIG. 10 is a graph showing optimum NpWp of the P⁻ layers 4 as a ratio to NnWn of the JFET-N layers 5. A lateral axis of the graph expresses a ratio of NpWp in the P⁻ layers 4 to NnWn in the JFET-N layers 5, (NpWp/NnWn). A vertical axis of the graph expresses numerals standardized by a performance index (FOM (Figure of Merit): (power of 2.5 of breakdown voltage/on-resistance) of a conventional configuration in which the JFET-N layers 5 are formed shallowly and no P⁻ layers 4 are provided.

It is clear from FIG. 10 that a performance index equal to or higher than 1 is obtained within a range of 0.6<(NpWp/NnWn)≦5.7.

As explained above, by deeply forming the P⁻ layers 4, drift resistance can be also decreased by optimizing impurity concentration of the P⁻ layers 4 as well as decreasing the JFET resistance. Consequently, lowering of on-resistance can be achieved.

Further, by providing the configuration of the present embodiment, high avalanche resistance can be realized. To improve the avalanche resistance, it is effective to increase a termination breakdown voltage and to make it difficult to operate a parasitic bipolar transistor within the cell. As described above, based on the configuration of the present embodiment, the termination breakdown voltage can be increased. When the P⁻ layers 4 are provided beneath the P-base layers 6 of the cell to shift the electric field peak to the bottom of the P⁻ layers 4, avalanche breakdown in the cell occurs on the bottom of the P⁻ layers 4. Based on the avalanche breakdown, even when holes are generated, the holes pass straight from the bottom of the P⁻ layers 4 to the source electrode 11. Therefore, the holes do not flow under the N⁺ source layers, and the parasitic bipolar transistor cannot operate easily. From the above effects, high avalanche breakdown can be achieved.

From the viewpoint of decreasing the on-resistance, the JFET-N layers 5 need to be formed deeper than the P-base layers 6. To securely set the electric-field peak position at the bottom of the P⁻ layers 4, preferably, the P⁻ layers 4 are formed deeper than the JFET-N layers 5, as shown in a first modification in FIG. 11.

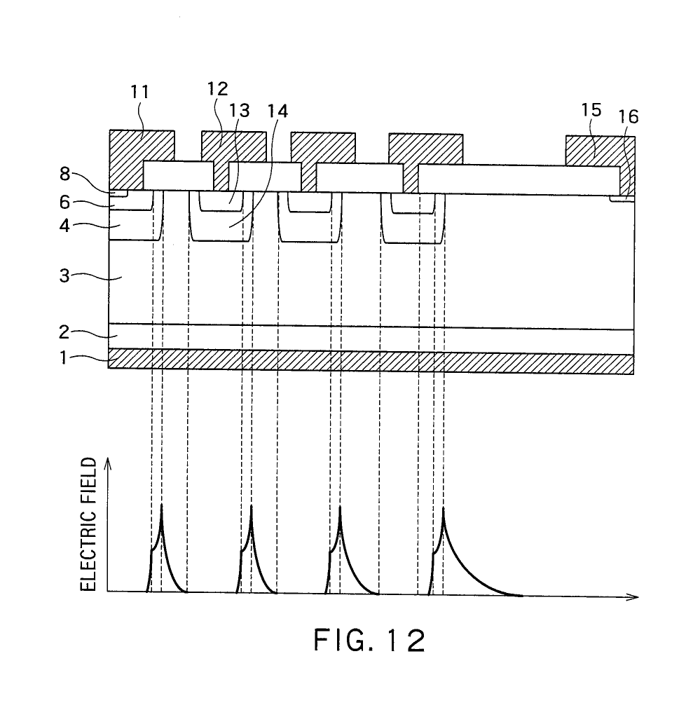

In the terminating region, preferably, impurity concentration of the P⁻ guard ring layers 14 formed to cover the guard ring layers 13 is also the impurity concentration by which the P⁻ guard ring layers 14 are completely depleted when a high voltage is applied to the guard ring layers 14 in a similar manner to that of the P⁻ layers 4. FIG. 12 shows a cross-sectional configuration of the terminating region in a second modification of the present embodiment and a lateral-direction electric-field distribution in the top surface thereof. As shown in FIG. 12, when the P⁻ guard ring layers 14 are depleted, the electric field peak locates in the external end portion of the P⁻ guard ring layers 14 not in the external end portion of the guard ring layers 13. Therefore, a curvature radius of the external end portion becomes large, and a high breakdown voltage can be easily obtained in a similar manner to that when the guard ring layers 13 become deep.

### (6) Sixth Embodiment

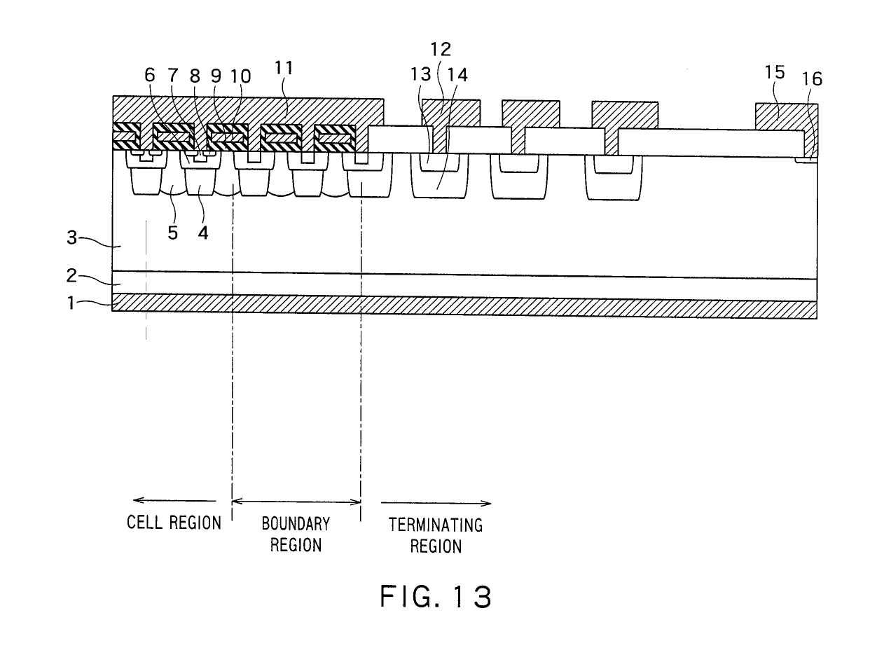

FIG. 13 is a cross-sectional view schematically showing a configuration of a semiconductor device according to a sixth embodiment of the present invention.

As is clear from a comparison between FIG. 6 and FIG. 13, a power MOSFET according to the present embodiment further has a boundary region provided between the cell region and the terminating region. In this boundary region, the gate electrodes 10 are formed, but the N⁺ source layers 8 are not formed. Therefore, even when a gate voltage is applied, no current flows to the boundary region. Other configurations of the power MOSFET according to the present embodiment are substantially the same as the configurations shown in FIG. 6.

Usually, inside the terminating region, no MOS gate is formed, and a region is provided in which only the P-base layers 6 connected to the source electrode 11 are formed to discharge holes from the terminating region. In other embodiments of the present invention such as the fourth embodiment shown in FIG. 6, for example, the P-base layer 36 at the outermost is also formed in a larger width than that of the P-base layers 6 in the cell region. However, when the width of the P-base layer 36 is large, a width of the P⁻ layer 34 formed beneath this layer also becomes large.

As described above, in the cell region, a depletion layer in the P⁻ layers is extended in the lateral direction from the PN junction with the JFET-N layers 5. However, because the width of the P⁻ layer 34 in the terminating region is large, the P⁻ layer 34 is not easily depleted. Consequently, the termination breakdown voltage easily decreases. Therefore, in the present embodiment, as shown in FIG. 13, the P⁻ layers 4 and the JFET-N layers 5 are formed at the same pitch as that in the cell region inside the terminating region. Accordingly, the P⁻ layers 4 can be easily depleted, and decrease of the termination breakdown voltage can be suppressed.

When avalanche breakdown occurs or when an incorporated diode is operated, concentrated holes flow from the terminating region into the boundary region. Because the N⁺ source layers 8 are not formed in the boundary region, a parasitic bipolar transistor is not formed. Therefore, even when a large hole current flows, a parasitic bipolar transistor does not operate, and high avalanche resistance and recovery resistance can be obtained.

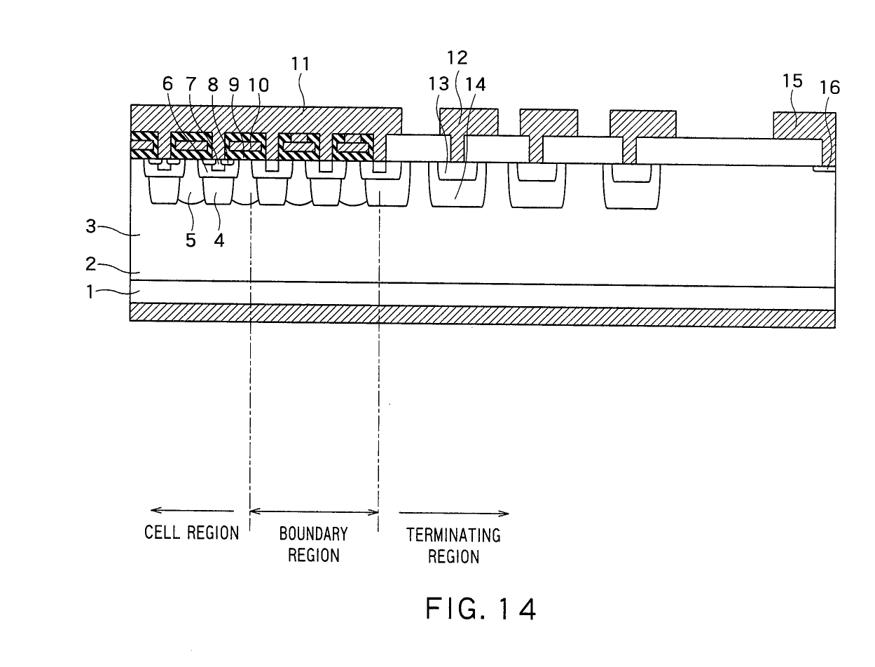

Furthermore, because the N⁺ source layers 8 are not formed in the boundary region, no current flows in the on-state, even when a MOS gate structure is formed. Therefore, as shown in a modification in FIG. 14, even when the gate electrodes 10 in the boundary region are connected to the source electrodes 11, on-resistance does not increase. Based on this configuration, increase of capacitance between the gate and the source due to the gate electrode in the boundary region can be avoided.

### (7) Seventh Embodiment

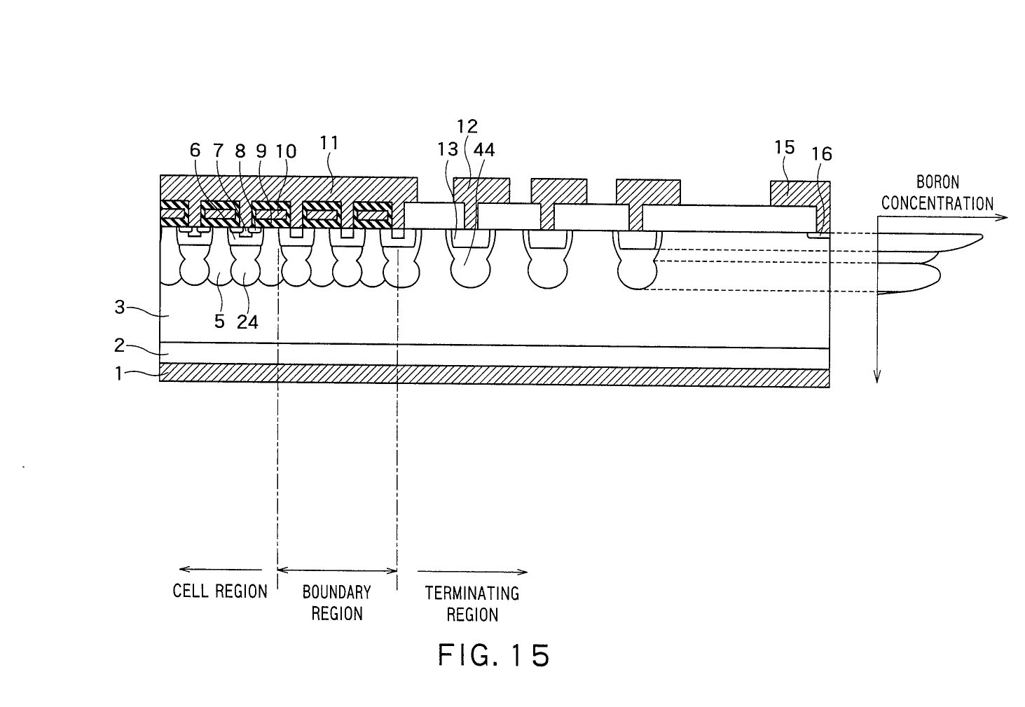

FIG. 15 is a cross-sectional view schematically showing a configuration of a semiconductor device according to a seventh embodiment of the present invention.

As is clear from a comparison between FIG. 6 and FIG. 15, a power MOSFET according to the present embodiment has a characteristic in that the power MOSFET includes a P⁻ layer 24 and a guard ring layer 44 formed in a deep region of the N⁻ drift layer 3 by connecting two P-type doped layers formed in the vertical direction. Other configurations of the power MOSFET in the present embodiment are substantially the same as those of the power MOSFET shown in FIG. 6.

When the P⁻ layers 4 are deeply formed as is shown in FIG. 15, the JFET-P layers 5 can be also deeply formed, and on-resistance can be decreased. However, it is difficult to deeply form the P⁻ layer 4 by only performing diffusion from the surface.

By a high-speed ion implantation, impurity can be doped into a deep position in advance. Accordingly, the P⁻ layer 4 can be formed deeper than that when only thermal diffusion is performed. When acceleration energy is set to 3 MeV, ion implantation can be performed to a depth of about 4 μm from the surface. When diffusion after the high-speed ion implantation is combined with diffusion from the surface, an impurity profile shown in the right portion of the sheet of FIG. 15 is obtained, and this profile has a peak in a depth direction. In addition, when high-speed ion implantation is also used in the JFET-N layers 5, the JFET-N layers 5 can be also deeply formed.

While FIG. 15 shows a configuration formed by performing high-speed ion implantation at one time, the configuration can be also formed by performing the high-speed ion implantation at plural times with an acceleration voltage being changed.

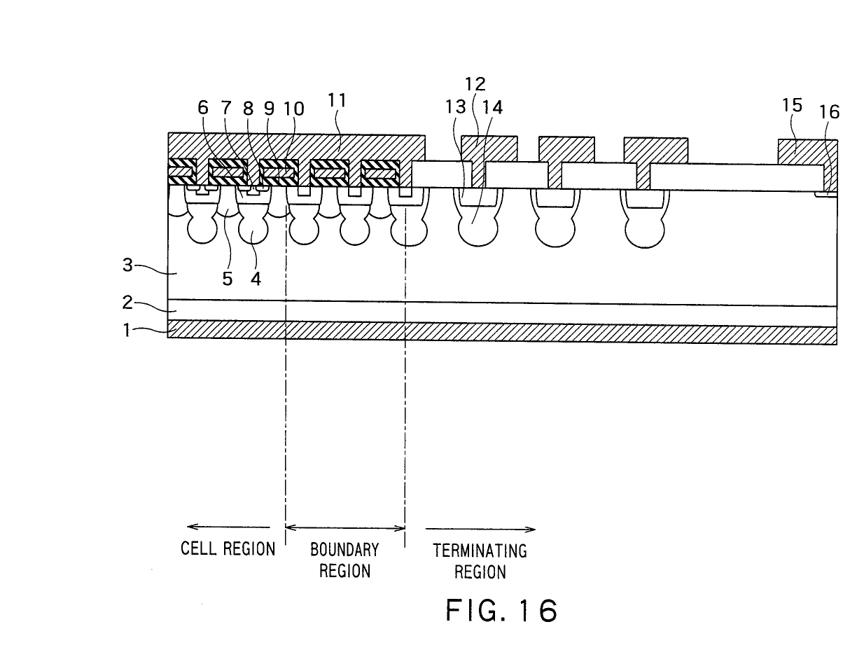

As shown in a first modification in FIG. 16, it is possible to securely form the P⁻ layers 4 deeper than the JFET-N layers 5 by deeply forming only the P⁻ layers 4 with the use of high-speed ion implantation and forming the JFET-N layers 5 without using high-speed ion implantation. Consequently, an electric-field peak position can be set securely to the bottom of the P⁻ layers 4.

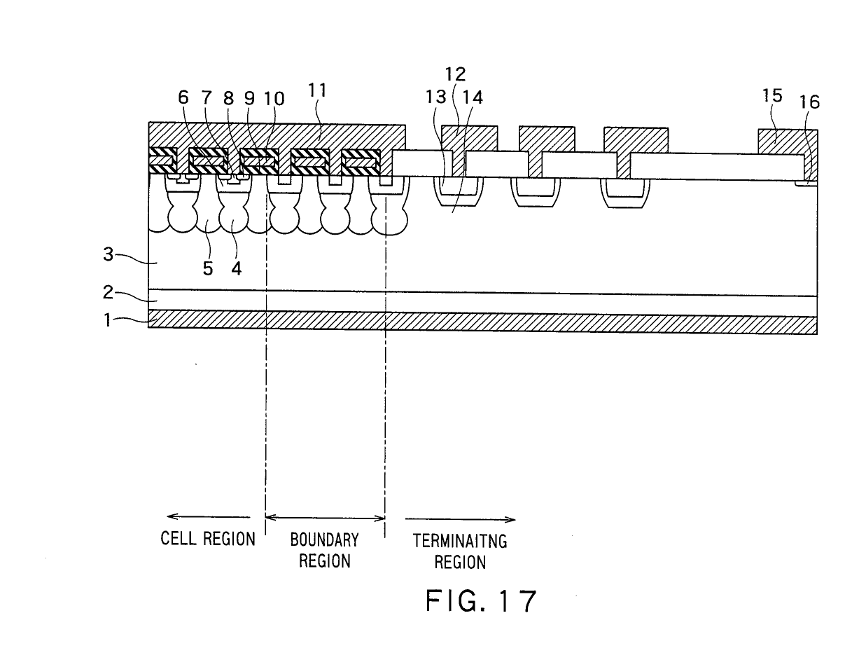

As shown in a second modification in FIG. 17, the P⁻ layers 4 and the JFET-N layers 5 can be deeply formed, and the P⁻ guard ring layers 14 can be shallowly formed to have a similar effect. When the P⁻ layers 4 and the JFET-N layers 5 are formed deeper, on-resistance can be decreased. On the other hand, when the P⁻ guard ring layers 14 are formed in a certain level of depth, a curvature radius becomes large against the impurity concentration of an electric field in the terminating region, and a high breakdown voltage can be obtained. When the P⁻ guard ring layers 14 are formed too deep, the P⁻ guard ring layers 14 are not easily depleted, and thus the termination breakdown voltage may be decreased. Therefore, the P⁻ guard ring layers 14 can be formed shallower than the P⁻ layers 4. This configuration can be provided by forming the P⁻ guard ring layers 14 with the use of low-speed ion implantation and by forming the P⁻ layers 4 with the use of both low-speed and high-speed ion implantation, respectively.

### (8) Eighth Embodiment

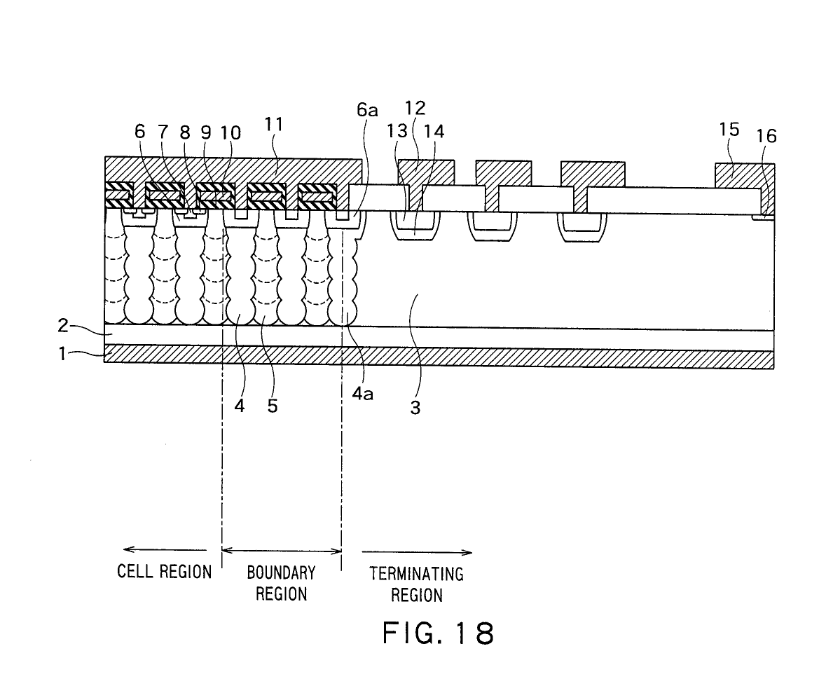

FIG. 18 is a cross-sectional view schematically showing a configuration of a semiconductor device according to an eighth embodiment of the present invention.

As is clear from a comparison between FIG. 6 and FIG. 18, a power MOSFET according to the present embodiment has a characteristic in that the P⁻ layers 4 and the JFET-N layers 5 are formed in a depth to reach the N⁺ drain layer 2. By employing this configuration, the impurity concentration of the drift layer becomes high in whole, and lowering of on-resistance can be achieved. In this configuration, when an end portion of a P-base layer 6a in a cross-sectional direction and an external end portion of the guard ring layer 13 are covered by a P⁻ layer 4a and the P⁻ guard ring layer 14, respectively, electric field concentration can be relaxed and a high breakdown voltage can be realized. Other configurations of the power MOSFET according to the present embodiment are substantially the same as those of the power MOSFET shown in FIG. 6.

A configuration that the P⁻ layers 4 and the JFET-N layers are extended from the surface layer to the bottom surface of the N⁻ drift layer 3 can be formed by performing high-speed ion implantation plural times in which an accelerated voltage is changed and by a method of repeating ion implantation and embedded crystal growth plural times. Therefore, the P⁻ layers 4 formed by impurity diffusion from the surface by low-speed ion implantation and the P⁻ layers 4 formed by embedding do not need to have the same patterns.

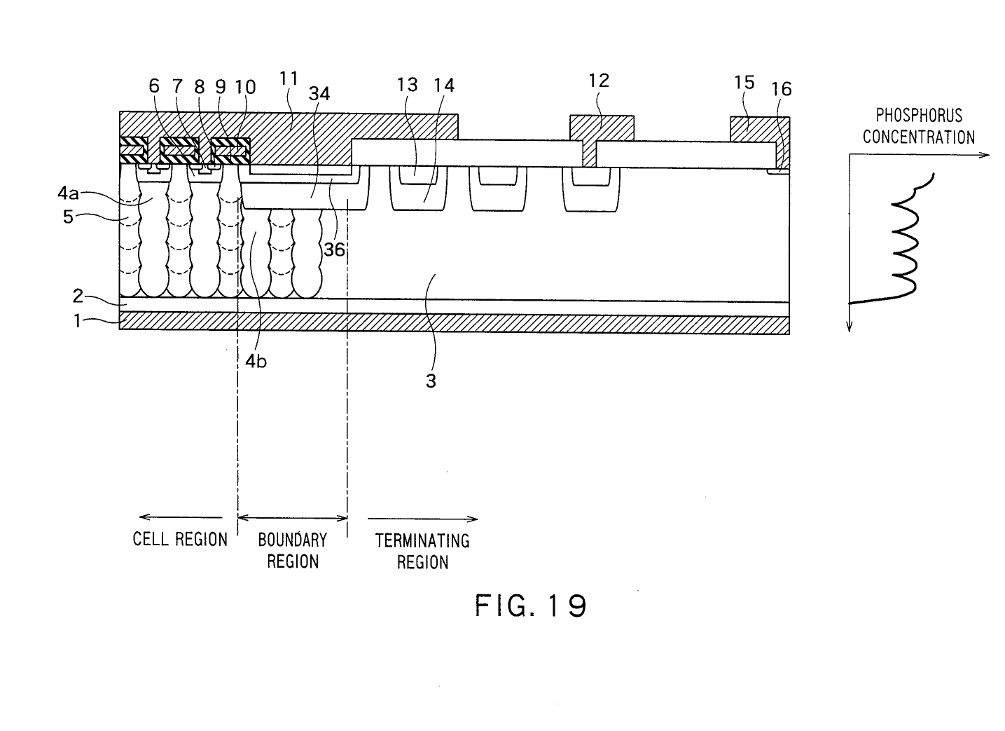

In a first modification shown in FIG. 19, the P⁻ layer 34 is formed uniformly in a boundary region of a surface layer of the N⁻ drift layer 3. P⁻ layers 4b embedded between the P⁻ layer 34 and the N⁺ drain layer 2 are formed in the same cycle as that of the P⁻ layers 4a in the cell region. While both the P⁻ layer 34 and the P⁻ layers 4b are completely depleted when a high voltage is applied, there is no need to form the P layer 34 and the P⁻ layers 4b so as to have the same impurity concentration.

Because the P⁻ layers 4a and the JFET-N layers 5 have higher impurity concentration than that in the N⁻ drift layer 3, the P⁻ layers 4a and the JFET-N layers 5 are not easily depleted. Therefore, electric field concentration occurs easily in the boundary region between the terminating region and the cell region as well. To avoid decrease of the breakdown voltage due to the electric field concentration in the boundary region, it is preferable that the impurity concentration of the P⁻ layers 4b and the JFET-N layers 5 in the boundary region is low. Since no MOS gate is formed and no current flows in the boundary region, on-resistance does not increase even when impurity concentration is low. In accordance of the configuration of the example shown in FIG. 19, impurity concentration of the P⁻ layers 4 and the JFET-N layers 5 has plural peaks. An impurity concentration profile of the JFET-N layers 5 is shown in a phosphorus impurity concentration profile in the right portion of the sheet of FIG. 19. However, the impurity concentration distribution of the P⁻ layers 4 and the JFET-N layers 5 is not limited to this example, and the P⁻ layers 4 and the JFET-N layers 5 can be formed by only diffusing from the surface of the N⁻ drift layer 3.

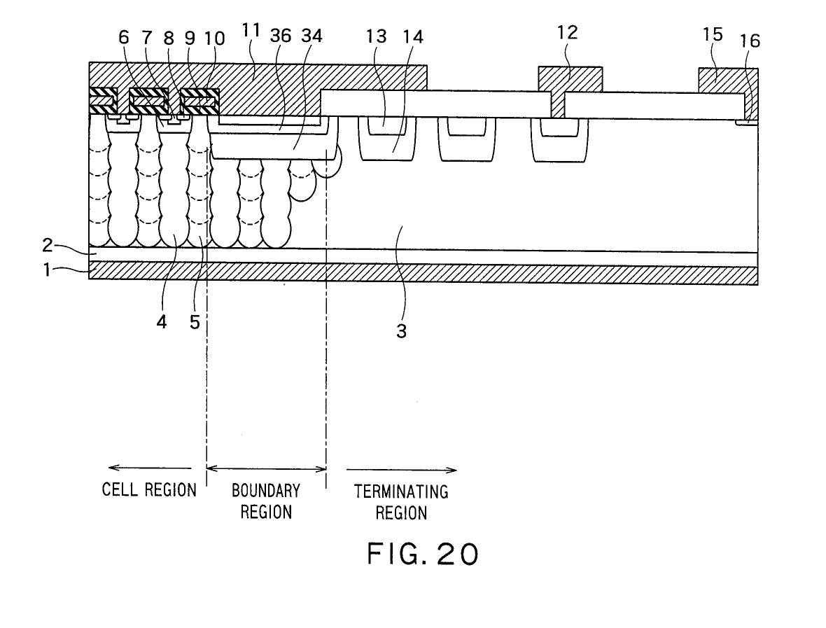

As shown in a second modification in FIG. 20, when the P⁻ layers 4 and the JFET-N layers 5 are formed to be gradually shallower toward the outside, a similar effect to that when the impurity concentration is set gradually low can be achieved.

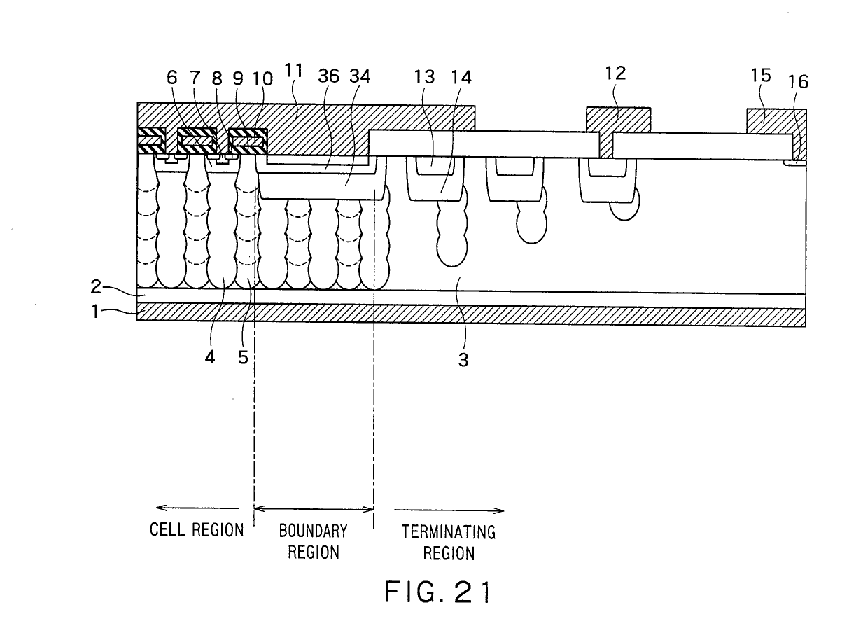

Also in the present embodiment, decrease of the breakdown voltage is suppressed by forming the P⁻ layers 4 and the P⁻ guard ring layers 14 in a portion where an electric field is easily concentrated. Because the curvature radius in the cross-sectional direction becomes larger toward the outside, the P⁻ guard ring layers 14 can be shallow. Therefore, as shown in a third modification in FIG. 21, the depth of the P⁻ guard ring layers 14 can be changed.

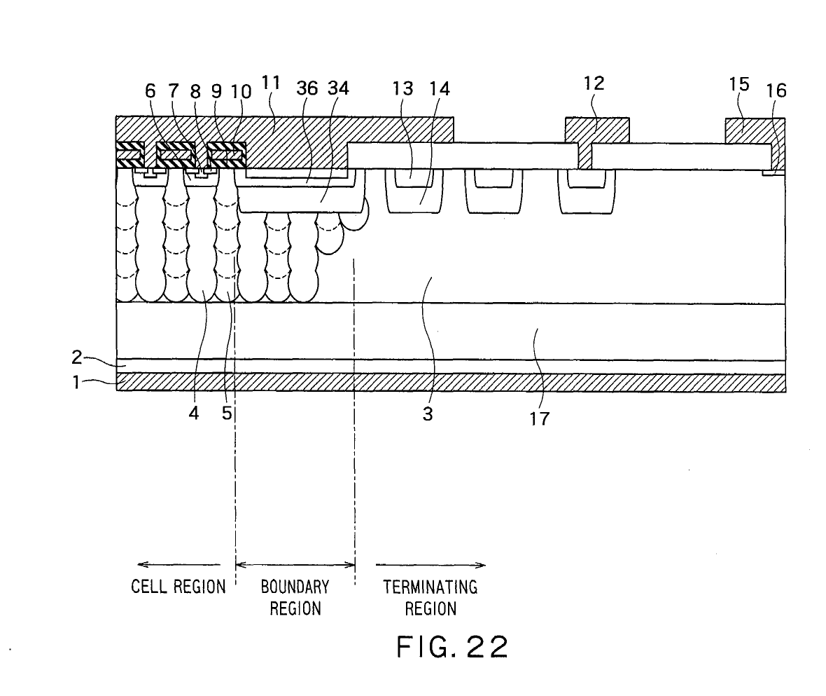

Furthermore, as shown in a fourth modification in FIG. 22, an N buffer layer 17 can be formed between the P⁻ layers 4 and the JFET-N layers 5, and the N⁺ drain layer 2. When the N buffer layer 17 is inserted between these layers, a higher breakdown voltage than that in the configuration of the second modification shown in FIG. 20 can be easily obtained. When the N buffer layer 17 has higher impurity concentration than that in the N⁻ drift layer 3, lower on-resistance than that in the configuration shown in FIG. 6 can be obtained.

While exemplary embodiments of the present invention have been explained above, the present invention is not limited to these embodiments, and can be applied in various modifications within the scope of the invention. For example, while the first conductive type is the N-type and the second conductive type is the P-type in the above explanations, the first conductive type can be the P-type and the second conductive type can be the N-type.

While plane patterns of the P⁻ layer and the gate electrode are not particularly shown in the first to eighth embodiments, these patterns are not limited to a stripe shape and can be a mesh shape, offset mesh shape, or honeycomb shape.

Furthermore, the above embodiments can be combined as appropriate.

What is claimed is:

1. A semiconductor device comprising:
a first semiconductor layer of a first conductivity type comprising a first surface and a second surface opposite to the first surface, a cell region, and a terminal region surrounding the cell region, the cell region being configured to allow a current to flow between the first surface and the second surface;
a first guard ring layer of a second conductivity type selectively formed in a surface portion of the first semiconductor layer in the terminal region, the first guard ring layer comprising a bottom surface thereof and internal and external side surfaces thereof; and
a second guard ring layer of the second conductivity type selectively formed in the surface portion of the first semiconductor layer in the terminal region so as to cover a portion of the first guard ring layer at which the bottom surface and the external side surface intersect, the impurity concentration of the second guard ring being a level at which the second guard ring layer is completely depleted by application of a high voltage.

2. The device of claim 1, further comprising:
a plurality of second semiconductor layers of the second conductivity type selectively formed in a surface portion of the first semiconductor layer in the cell region on a first side thereof;
a third semiconductor layer of the first conductivity type selectively formed in the surface portion of the first semiconductor layer so as to be sandwiched between the second semiconductor layers;
a fourth semiconductor layer of the first conductivity type selectively formed in a surface portion of the second semiconductor layers;
a first main electrode on a second side of the first semiconductor layer opposite to the first side and electrically connected to the first semiconductor layer;
a second main electrode on the first side of the first semiconductor layer and in contact with a surface of the second semiconductor layer and a surface of the fourth semiconductor layer; and
a control electrode on an insulating film on the second semiconductor layers, the third semiconductor layer and the fourth semiconductor layer.

3. The device of claim 2, further comprising:
a fifth semiconductor layer of the second conductivity type beneath the second semiconductor layer and in contact with a bottom surface of the second semiconductor layer.

4. The device of claim 3,
wherein the fifth semiconductor layer has impurity concentration at a level at which the fifth semiconductor layer is completely depleted when a high voltage is applied to the fifth semiconductor layer.

5. The device of claim 4,
wherein the second through fifth semiconductor layers and the control electrode are cyclically formed in a first direction parallel to a surface of the first semiconductor layer on the first side, and
a first product of impurity concentration of the fifth semiconductor layer and a width of the fifth semiconductor layer in the first direction is within a range from 0.6 times a second product of impurity concentration of the third semiconductor layer and a width of the third semiconductor layer in the first direction to 5.7 times the second product.

6. The device of claim 3,
wherein a bottom surface of the fifth semiconductor layer is deeper than that of the third semiconductor layer.

7. The device of claim 3,
wherein a bottom surface of the third semiconductor layer is deeper than that of the second semiconductor layer.

8. The device of claim 3,
wherein impurity concentration of the fifth semiconductor layer has at least one peak in depth direction.

9. The device of claim 3,
wherein the first semiconductor layer further has a boundary region locating between the cell region and the terminating region and surrounding the cell region, and
the boundary region comprises the same semiconductor layers as the second, third and fifth semiconductor layers except the fourth semiconductor layer.

10. The device of claim 3,
wherein each bottom surface of the third and fifth semiconductor layers is deeper than that of the second guard ring layer.

11. The device of claim 3,
wherein each bottom surface of the third and fifth semiconductor layers contacts a bottom surface of the first semiconductor layer.

12. The device of claim 2, further comprising a buffer layer of the first conductivity type between the first semiconductor layer and the first main electrode.

13. The device of claim 1,
wherein the depth of the second guard ring layers changes in a manner that the second guard ring layers become shallower as they come near a peripheral border of the device.

14. The device of claim 2,
wherein a position of a bottom surface of the second semiconductor layer is substantially the same as a position of a bottom surface of the first guard ring layer.

15. The device of claim 3,
wherein a position of a bottom surface of the fifth semiconductor layer is substantially the same as a position of a bottom surface of the second guard ring layer.

16. The device of claim 9,
wherein the control electrode extends over the boundary region and contacts the second main electrode within the boundary region.

17. The device of claim 1, further comprising a field plate electrode connected electrically to the first guard ring layer.

18. The device of claim 16,
wherein the number of the first guard ring layers is two or more, and
the field plate electrode is electrically connected only to a part of the first guard ring layers.

19. The device of claim 1, further comprising:
a plurality of second semiconductor layers of the second conductivity type selectively formed in a surface portion of the first semiconductor layer in the cell region on a first side thereof;
a third semiconductor layer of the first conductivity type selectively formed in the surface portion of the first semiconductor layer so as to be sandwiched between the second semiconductor layers;
a fourth semiconductor layer of the first conductivity type selectively formed in a surface portion of the second semiconductor layers;
a sixth semiconductor layers of the second conductivity type on a second side of the first semiconductor layer opposite to the first side and electrically connected to the first semiconductor layer;
a first main electrode on the second side of the first semiconductor layer and electrically connected to the fifth semiconductor layer;
a second main electrode on the first side of the first semiconductor layer and in contact with a surface of the second semiconductor layer and a surface of the fourth semiconductor layer; and
a control electrode on an insulating film on the second semiconductor layers, the third semiconductor layer and the fourth semiconductor layer.

20. The device of claim 1, further comprising:
a second semiconductor layer of the second conductivity type in a surface layer of the first semiconductor layer in the cell region;
a first main electrode on a first side of the first semiconductor layer and electrically connected to the second semiconductor layer; and
a second main electrode on a second side of the first semiconductor layer opposite to the first side and electrically connected to the first semiconductor layer.
